(19) United States
(12) Patent Application Publication
(10) Pub. No.: US 2024/0290678 A1
(43) Pub. Date: Aug. 29, 2024

(54) SEMICONDUCTOR STRUCTURE AND METHOD FOR PREPARING SAME, MEMORY, AND ELECTRONIC DEVICE

(71) Applicant: BEIJING SUPERSTRING ACADEMY OF MEMORY TECHNOLOGY, Daxing District, Beijing (CN)

(72) Inventor: Ming ZENG, Beijing (CN)

(73) Assignee: BEIJING SUPERSTRING ACADEMY OF MEMORY TECHNOLOGY, Daxing District, Beijing (CN)

(21) Appl. No.: 18/705,226

(22) PCT Filed: Jun. 7, 2023
(86) PCT No.: PCT/CN2023/098851

§ 371 Date: Apr. 26, 2024

(30) Foreign Application Priority Data
Feb. 13, 2023 (CN) 202310151552.1

(51) Int. Cl. H01L 23/31; H01L 21/56

(52) U.S. Cl. CPC H01L 23/3178; H01L 21/56

(57) ABSTRACT

Provided is a semiconductor structure. The semiconductor structure includes a substrate including a die region and a non-die region, wherein an accommodation recess is formed in a side of the substrate and positioned in the non-die region; a buffer disposed in the accommodation recess; a functional film layer disposed on the side, where the accommodation recess is formed, of the substrate; and a passivation layer covering the functional film layer and the substrate. A buffer cavity with an opening facing away from the substrate is formed in the buffer. An orthographic projection of the functional film layer on the substrate is within the die region. A first through-via is formed in the passivation layer. An orthographic projection of the first through-via on the substrate is at least partially overlapped with an orthographic projection of the opening on the substrate. The opening is in communication with the first through-via.

### CROSS-REFERENCE TO RELATED APPLICATIONS

This application is a U.S. national stage of International Application No. PCT/CN2023/098851, filed on Jun. 7, 2023, which claims priority to Chinese Patent Application No. 202310151552.1, filed on Feb. 13, 2023, and entitled “SEMICONDUCTOR STRUCTURE AND PREPARATION METHOD THEREOF, MEMORY AND ELECTRONIC EQUIPMENT,” the contents of which are incorporated herein by reference in their entireties.

### TECHNICAL FIELD

The present disclosure relates to the technical field of semiconductors, and in particular, relates to a semiconductor structure and a method for preparing the same, and a memory.

### BACKGROUND

In the current front-end-of-line for the production of semiconductor structures, there are differences between parameters such as the coefficients of thermal expansion of the various film-layer materials deposited on the substrate during the production process and parameters such as the coefficient of thermal expansion of the substrate materials, and thus the wafer is subject to warpage upon various high-temperature treatment processes, which affects the performance of semiconductor structures.

### SUMMARY

The present disclosure provides a semiconductor structure and a method for preparing the same, a memory, and an electronic device.

According to some embodiments of the present disclosure, a semiconductor structure is provided. The semiconductor structure includes:
a substrate including a die region and a non-die region disposed on a periphery of the die region, wherein an accommodation recess is formed in a side of the substrate, the accommodation recess being positioned in the non-die region;
a buffer disposed in the accommodation recess, wherein a buffer cavity with an opening facing toward a side, facing away from the substrate, of the buffer is formed in the buffer;
a functional film layer disposed on the side, where the accommodation recess is formed, of the substrate, wherein an orthographic projection of the functional film layer on the substrate is within the die region; and
a passivation layer covering the functional film layer and the substrate, wherein a first through-via is formed in the passivation layer, an orthographic projection of the first through-via on the substrate being at least partially overlapped with an orthographic projection of the opening on the substrate, and the opening being in communication with the first through-via.

In some embodiments of the present disclosure, along a direction perpendicular to the substrate, a depth of the accommodation recess is greater than or equal to 3 μm.

In some embodiments of the present disclosure, a difference between a coefficient of thermal expansion of the buffer and a coefficient of thermal expansion of the substrate is within a first predetermined range, and the coefficient of thermal expansion of the buffer is close to or less than the coefficient of thermal expansion of the substrate; and/or
a difference between a coefficient of thermal expansion of the passivation layer and a coefficient of thermal expansion of the substrate is within a second predetermined range, and the coefficient of thermal expansion of the passivation layer is close to or less than the coefficient of thermal expansion of the substrate.

In some embodiments of the present disclosure, the substrate is a silicon substrate;
the coefficient of thermal expansion of the buffer is greater than or equal to 0 and less than or equal to a coefficient of thermal expansion of silicon dioxide; and
the coefficient of thermal expansion of the passivation layer is greater than or equal to 0 and less than or equal to the coefficient of thermal expansion of silicon dioxide.

In some embodiments of the present disclosure, a material of the buffer includes silicon dioxide or carbon; and/or
a material of the passivation layer includes silicon dioxide or carbon.

In some embodiments of the present disclosure, in a section parallel to the substrate, a section of the accommodation groove is in a linear shape, the linear shape including at least one of a straight line shape, a folded line shape, or an arc shape; and/or
in a section perpendicular to the substrate, the accommodation recess is in a shape with a wide upper part and a narrow lower part, a shape with a narrow upper part and a wide lower part, a rectangular shape, a circular shape, or an elliptical shape.

In some embodiments of the present disclosure, a plurality of the accommodation recesses are formed in the side of the substrate, the plurality of the accommodation recesses being successively spaced apart along a predetermined direction or spaced apart in an array.

In some embodiments of the present disclosure, the semiconductor structure further includes a protection layer, wherein the protection layer is formed on a side, facing toward the functional film layer, of the substrate, and a second through-via is formed in the protection layer, an orthographic projection of the second through-via on the substrate being at least partially overlapped with the orthographic projection of the opening on the substrate.

In some embodiments of the present disclosure, the buffer is filled into the accommodation recess and the second through-via; wherein
within a section perpendicular to the substrate, the buffer cavity is at least partially overlapped with the accommodation recess; and/or
within a section perpendicular to the substrate, the buffer cavity is at least partially overlapped with the second through-via.

According to some embodiments of the present disclosure, a memory is provided. The memory includes the semiconductor structure as described above.

According to some embodiments of the present disclosure, an electronic device is provided. the electronic device includes the memory as described above.

According to some embodiments of the present disclosure, a method for preparing a semiconductor structure is provided. The method includes:
providing a substrate, wherein the substrate includes a die region and a non-die region disposed on a periphery of the die region;
preparing an accommodation recess in a side of the substrate, wherein the accommodation recess is positioned in the non-die region;
preparing a buffer structure in the accommodation recess, wherein a closed buffer cavity is formed in the buffer structure;
preparing a functional film layer on the side, where the accommodation recess is formed, of the substrate, wherein an orthographic projection of the functional film layer on the substrate is within the die region;
preparing a passivation layer on a side, away from the substrate, of the functional film layer, wherein the passivation layer covers the functional film layer and the buffer structure; and
patterning the passivation layer and the buffer structure, such that a first through-via is formed in the passivation layer, and an opening facing toward a side, facing away from the substrate, of the buffer structure is formed in the buffer cavity, wherein the patterned buffer structure forms a buffer, an orthographic projection of the first through-via on the substrate is at least partially overlapped with an orthographic projection of the opening on the substrate, and the opening is in communication with the first through-via.

In some embodiments of the present disclosure, prior to preparing the accommodation recess in the side of the substrate, the method further includes:
preparing a protection layer on a side of the substrate; and
preparing the accommodation recess in the side of the substrate includes:
patterning the protection layer and the substrate, such that a second through-via is formed in the protection layer, and the accommodation recess is formed in the substrate, wherein an orthographic projection of the second through-via on the substrate is at least partially overlapped with an orthographic projection of the accommodation recess on the substrate.

In some embodiments of the present disclosure, preparing the buffer structure in the accommodation recess includes:
filling the accommodation recess with a buffer material and forming the buffer structure with the closed buffer cavity by controlling a filling rate of the buffer material; wherein a difference between a coefficient of thermal expansion of the buffer material and a coefficient of thermal expansion of the substrate is within a first predetermined range, and the coefficient of thermal expansion of the buffer material is close to or less than the coefficient of thermal expansion of the substrate.

In some embodiments of the present disclosure, prior to preparing the functional film layer on the side, where the accommodation recess is formed, of the substrate, the method further includes:
performing a planarization process on the protection layer and the buffer structure, such that a surface of a side, away from the substrate, of the protection layer is flush with a surface of a side, facing away from the substrate, of the buffer structure.

Additional aspects and advantages of the present disclosure are partially given in the following description, and these would become apparent from the following description or through the practice of the present disclosure.

### BRIEF DESCRIPTION OF DRAWINGS

FIG. 1 is a schematic structural diagram of a substrate of a semiconductor structure according to some embodiments of the present disclosure;

FIG. 2 is a flowchart of a method for preparing a semiconductor structure according to some embodiments of the present disclosure; and

FIG. 3 to FIG. 7 are cross-sectional views along a direction A-A in FIG. 1 at different processes of the method for preparing a semiconductor structure according to some embodiments of the present disclosure.

### REFERENCE NUMERALS AND DENOTATIONS THEREOF

100-semiconductor structure; 10-substrate; 11-die region; 12-scribe line region; 13-accommodation recess; 20-buffer; 21-buffer cavity; 22-opening; 23-buffer structure; 30-functional film layer; 40-passivation layer; 41-first through-via; 50-protection layer; 51-second through-via.

### DETAILED DESCRIPTION

The present disclosure is described in further detail with reference to the accompanying drawings. It should be understood that the embodiments described in conjunction with the accompanying drawings hereinafter are exemplary descriptions for explaining the technical solutions of the embodiments of the present disclosure, and are not intended to construe any limitation to the technical solutions of the embodiments of the present disclosure.

It should be understood by those skilled in the art that the singular forms “one,” “a,” “the,” and “the” used herein, may also include the plural form, unless otherwise defined. It should be further understood that the terms “include” and “comprise” used in the specification of the present application refer to the presence of the described features, integers, steps, operations, elements, and/or components, but do not preclude the realization of other features, information, data, steps, operations, elements, components, and/or combinations thereof as supported in the art. It should be understood that when an element is “connected” or “coupled” to another element, the element may be connected or coupled directly to the other element, or it may indicate that the element establishes a connection relationship with the other element through an intermediate element. In addition, the terms “connected” or “coupled” used herein may include wireless connection or wireless coupling. The term “and/or” used herein refers to at least one of the items defined by the term. For example, “A and/or B” may be realized as “A”, or as “B”, or as “A and B.”

For clarity of the purposes, technical solutions, and advantages of the present disclosure, the embodiments of the present disclosure will be described in further detail hereinafter in conjunction with the accompanying drawings.

The related art is described hereinafter first.

In the current front-end-of-line for the production of semiconductor structures, because there are differences between parameters such as the coefficients of thermal expansion and Young's moduli of the various film-layer materials deposited on the substrate during the production process and parameters such as the coefficient of thermal expansion and Young's modulus of the substrate materials, the residual stress after various high-temperature treatment processes such as high-temperature activation and annealing leads to warpage of the wafer. In addition, as the number of film layers increases, the weight increases, which causes the pressure acting on the substrate to increase and also exacerbates the warping deformation of the wafer.

In conventional solutions, it is difficult to ameliorate the warping deformation of the wafer at the front-end-of-line stage, and therefore the warping deformation of the wafer generated in the front-end-of-line is left to be addressed in the back-end-of-line packaging process.

The semiconductor structure and the method for preparing the same, the memory, and the electronic device provided by the present disclosure are intended to address at least one of the problems in the related art as described above.

The technical solutions of the present disclosure and how the technical solutions of the present disclosure solve the above technical problems are described in detail hereinafter by the specific embodiments. It should be noted that the following embodiments may be referred to or combined with each other, and the same terms, similar features, and similar implementation steps in different embodiments will not be described repeatedly.

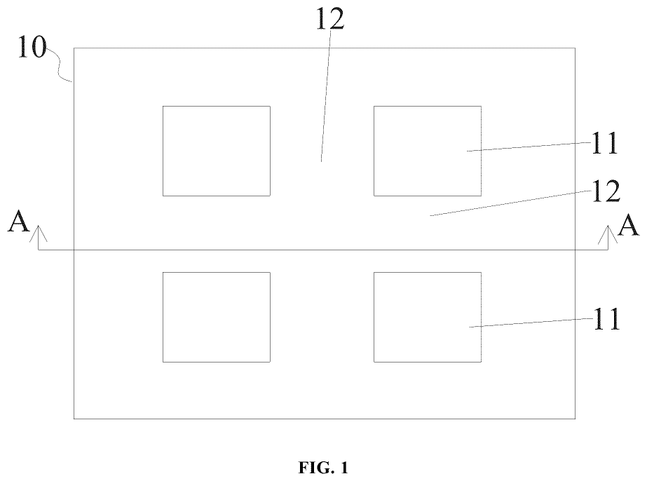

Some embodiments of the present disclosure provide a semiconductor structure, and the schematic structural diagram of the semiconductor structure 100 is shown in FIG. 1 and FIG. 7. FIG. 7 illustrates a schematic structural diagram of a semiconductor structure according to some embodiments of the present disclosure (the protection layer 50 is not shown in FIG. 7). The semiconductor structure 100 includes a substrate 10, a buffer 20, a functional film layer 30, and a passivation layer 40.

The substrate 10 includes a die region 11 and a non-die region disposed on a periphery of the die region 11. An accommodation recess 13 is formed in a side of the substrate 10, and the accommodation recess 13 is disposed in the non-die region.

A buffer 20 is disposed in the accommodation recess 13, and a buffer cavity 21 with an opening 22 facing toward a side, facing away from the substrate 10, of the buffer 20 is formed in the buffer 20.

The functional film layer 30 is disposed on the side of the substrate 10 having the accommodation recess 13, and an orthographic projection of the functional film layer 30 on the substrate 10 is disposed in the die region 11.

The passivation layer 40 covers the functional film layer 30 and the substrate 10, and a first through-via 41 is formed in the passivation layer 40. An orthographic projection of the first through-via 41 on the substrate 10 is at least partially overlapped with an orthographic projection of the opening 22 on the substrate 10, and the opening 22 is in communication with the first through-via 41.

In some embodiments of the present disclosure, the substrate 10 is configured to support the buffer 20, the functional film layer 30, and the passivation layer 40. The functional film layer 30 is disposed in the die region 11 of the substrate 10. The accommodation recess 13 is disposed in the non-die region of the substrate 10, and the accommodation recess 13 is configured to accommodate the buffer 20. The buffer 20 is disposed in the non-die region, and the buffer 20 has the buffer cavity 21 with the opening 22 facing toward the side, away from the accommodation recess 13, of the buffer 20. In this way, in the process of producing the semiconductor structure 100, in a case where the thermal stress is transferred to the buffer 20, due to the compressibility of the air, the buffer cavity 21 buffers the thermal stress and releases the thermal stress, such that the warping deformation of the wafer is alleviated or avoided, and thus the warping deformation of the wafer in the production process is addressed. Therefore, the impact of the thermal stress on the semiconductor structure 100 is reduced, and thus the production yield rate is improved, and the performance of the semiconductor structure is ensured.

In some embodiments of the present disclosure, the passivation layer 40 covers the functional film layer 30 and the substrate 10, the first through-via 41 is formed in the passivation layer 40, and the first through-via 41 is in communication with the opening 22, such that the buffer cavity 21 of the buffer 20 is in communication with the outside through the opening 22 and the first through-via 41 in sequence. In this way, the buffer cavity 21 buffers the thermal stress, such that the thermal stress is released timely and effectively, which helps to further enhance the improvement effect on the warping deformation of the wafer.

In some embodiments of the present disclosure, the functional film layer 30 is disposed in the die region 11 of the substrate 10, and the accommodation recess 13 is disposed in the non-die region of the substrate 10. A region where the functional film layer 30 is disposed is an effective region where an actual chip is disposed, and a region where the accommodation recess 13 is formed does not overlap with the effective region where the actual chip is disposed (i.e., the region where the functional film layer 30 is disposed). In this way, the interference between the accommodation recess 13 and the functional film layer 30 is avoided, and the normal production of the functional film layer 30 is ensured without affecting the current normal chip production process.

In some embodiments of the present disclosure, the functional film layer 30 includes various film layers, patterns, through-vias, injection regions, and the like that contribute to the actual chip functions (including but not limited to input/output circuits, amplifiers, logic calculations, data storage, and the like).

In some other embodiments of the present disclosure, the functional film layer 30 includes a plurality of chips successively stacked, and the chips include device structures and interconnect structures electrically connecting the device structures. The device structures include at least one of an active device and a passive device. The active devices include, for example, metal-oxide-semiconductor field-effect transistor (MOS) devices, memory devices, or other semiconductor devices. The passive devices include, for example, resistors, capacitors, or inductors.

It should be noted that in some embodiments of the present disclosure, the specific structure and arrangement of the functional film layer 30 are similar to those in the related art, which are not repeated herein.

In some embodiments of the present disclosure, the substrate 10 is a silicon substrate. In some embodiments of the present disclosure, the substrate 10 is made of other semiconductor materials according to practical needs, and the semiconductor material is one or more of germanium, silicon germanium compounds, and silicon carbon compounds.

In some embodiments of the present disclosure, the non-die region includes a scribe line region 12 disposed between adjacent two die regions 11, and the accommodation recess 13 is disposed in the scribe line region 12. In some embodiments of the present disclosure, the non-die region is made to include any other regions without chips as needed, such as all regions without patterns or regions only having dummy patterns. The accommodation recess 13 is disposed in all regions without patterns, or disposed in regions only having dummy patterns.

In some embodiments of the present disclosure, a depth h of the accommodation recess 13 is greater than or equal to 3 μm along a direction perpendicular to the substrate 10.

In a case where the depth h of the accommodation recess 13 is less than 3 μm, a size of the buffer 20 disposed within the accommodation recess 13 is reduced, and accordingly a size of the buffer cavity 21 is reduced. As a result, the buffer effect and the release effect of the buffer cavity 21 on the thermal stress are reduced accordingly. Although the warping deformation of the wafer is alleviated, the improvement effect is reduced.

In some embodiments of the present disclosure, the depth h of the accommodation recess 13 is greater than or equal to 3 μm, such that the sizes of the buffer 20 and the buffer cavity 21 are large. In this way, the buffer cavity 21 exerts an effective buffer effect and an effective release effect on the thermal stress, such that the warping deformation of the wafer is effectively addressed.

In some embodiments of the present disclosure, as shown in FIG. 4, in a section perpendicular to the substrate 10, the accommodation recess 13 is in an inverted trapezoidal shape. In some embodiments of the present disclosure, in the section perpendicular to the substrate 10, the shape of the accommodation recess 13 is similar to an inverted trapezoidal shape with a wide upper part and a narrow lower part, or similar to a trapezoidal shape with a narrow upper part and a wide lower part. In other embodiments of the present disclosure, the accommodation recess 13 in the section perpendicular to the substrate 10 is defined to be in a rectangular shape, a circular shape, an oval shape, or other shapes (including other regular shapes and irregular shapes) according to the actual needs, which is not limited herein.

In some embodiments of the present disclosure, in a section parallel to the substrate 10, a section of the accommodation recess 13 is in a linear shape, and the linear shape includes at least one of a straight line shape, a folded line shape, or an arc shape. In some other embodiments, the section of the accommodation recess 13 in the section parallel to the substrate 10 is defined to be in a rectangular shape, a circular shape, or other shapes, according to the actual needs.

In some embodiments of the present disclosure, at least one accommodation recess 13 is formed in a side of the substrate 10. In a case where a plurality of accommodation recesses 13 are formed in a side of the substrate 10, the plurality of accommodation recesses 13 are spaced apart, and the plurality of accommodation recesses 13 are disposed in the non-die region. Specifically, the plurality of accommodation recesses 13 are evenly spaced apart in a side of the substrate 10, for example, the accommodation recesses 13 are evenly spaced apart successively along a predetermined direction or evenly spaced apart in an array. In some embodiments, the plurality of accommodation recesses 13 are spaced apart in a side of the substrate 10 randomly or unevenly. The user may define the arrangement of the plurality of accommodation recesses 13 according to the actual needs and actual situation, as long as the plurality of accommodation recesses 13 are disposed in the non-die region and do not obstruct the die region.

In some embodiments of the present disclosure, the buffer 20 is made of a material with a coefficient of thermal expansion close to or lower than that of the material of the substrate 10. Specifically, the material of the substrate 10 is silicon (Si), and the coefficient of thermal expansion of the material of the buffer 20 is close to or lower than the coefficient of thermal expansion of Si.

In some embodiments of the present disclosure, a difference between the coefficient of thermal expansion of the buffer 20 and the coefficient of thermal expansion of the substrate 10 is within a first predetermined range, and the coefficient of thermal expansion of the buffer 20 is close to or less than the coefficient of thermal expansion of the substrate 10.

In some embodiments of the present disclosure, the coefficient of thermal expansion of the buffer 20 is greater than or equal to 0 and less than or equal to the coefficient of thermal expansion of silicon dioxide (SiO₂). In this case, the coefficient of thermal expansion of the buffer 20 is close to or lower than the coefficient of thermal expansion of the silicon substrate, such that the warping deformation of the wafer is alleviated or avoided, the warping deformation of the wafer during the production process is addressed, and the effect of thermal stress on the semiconductor structure 100 is reduced.

In some embodiments of the present disclosure, the buffer 20 with the buffer cavity 21 is prepared by making the accommodation recess 13 in the scribe line region 12 and filling the accommodation recess 13 with other materials (such as materials with a coefficient of thermal expansion less than or equal to that of SiO₂), to release stress and reduce the total coefficient of thermal expansion of the substrate.

In some embodiments of the present disclosure, the buffer 20 is made of SiO₂ (the coefficient of thermal expansion of SiO₂ is close to the coefficient of thermal expansion of Si) or carbon (C) (the coefficient of thermal expansion of C is less than the coefficient of thermal expansion of Si).

In some embodiments of the present disclosure, a difference between a coefficient of thermal expansion of the passivation layer 40 and the coefficient of thermal expansion of the substrate 10 is within a second predetermined range. The coefficient of thermal expansion of the passivation layer 40 is close to or less than the coefficient of thermal expansion of the substrate 10.

In some embodiments of the present disclosure, the coefficient of thermal expansion of the passivation layer 40 is greater than or equal to 0 and less than or equal to the coefficient of thermal expansion of SiO₂. In this case, the coefficient of thermal expansion of the passivation layer 40 is close to or lower than the coefficient of thermal expansion of the silicon substrate, such that the warping deformation of the wafer is alleviated or avoided, the warping deformation of the wafer during the production process is addressed, and the effect of thermal stress on the semiconductor structure 100 is reduced.

In some embodiments of the present disclosure, the passivation layer is made of a material with a coefficient of thermal expansion close to or lower than that of Si.

In some embodiments of the present disclosure, the passivation layer 40 is made of SiO₂ or C.

The coefficient of thermal expansion (CTE) of Si is 2.5×10⁻⁶/K. In some embodiments of the present disclosure, the buffer 20 and the passivation layer 40 are made of a material with a coefficient of thermal expansion close to or lower than that of Si.

In some embodiments of the present disclosure, as shown in FIG. 4 and FIG. 5, the semiconductor structure 100 further includes a protection layer 50. The protection layer 50 is disposed on a side, facing toward the functional film layer 30, of the substrate 10. A second through-via 51 is formed in the protection layer 50, and an orthographic projection of the second through-via 51 on the substrate 10 is at least partially overlapped with the orthographic projection of the opening 22 on the substrate 10.

In some embodiments of the present disclosure, the protection layer 50 protects the substrate 10, such that the functions of oxidation resistance and prevention of moisture invasion are achieved, and the etching solution is prevented from affecting regions of the substrate 10 other than the region where the accommodation recess 13 needs to be formed, especially the die region during the process of forming the accommodation recess 13. The buffer cavity 21 is in communication with the outside through the opening 22, the second through-via 51, and the first through-via 41 successively. In this way, the buffer cavity 21 buffers the thermal stress, such that the thermal stress is timely and effectively released, which helps to further enhance the improvement effect on the warping deformation of the wafer.

In some embodiments of the present disclosure, the buffer 20 is filled into both the accommodation recess 13 and the second through-via 51, and in the section perpendicular to the substrate 10, the buffer cavity 21 is at least partially overlapped with the accommodation recess 13. In some embodiments, in the section perpendicular to the substrate 10, the buffer cavity 21 is at least partially overlapped with the second through-via 51. In some embodiments, in the section perpendicular to the substrate 10, the buffer cavity 21 is at least partially overlapped with the accommodation recess 13 only, and is not overlapped with the second through-via.

In some embodiments of the present disclosure, the material of the protection layer 50 includes, but is not limited to, SiO₂.

Some embodiments of the present disclosure provide a semiconductor structure. The buffer 20 with the buffer cavity 21 is prepared by making the accommodation recess 13 in the scribe line region 12 and filling the accommodation recess 13 with other materials (such as materials with a coefficient of thermal expansion less than or equal to that of SiO₂), such that the stress is released and the total coefficient of thermal expansion of the substrate is reduced. Furthermore, the top passivation layer is formed by depositing a material with a low coefficient of thermal expansion (such as a material with a coefficient of thermal expansion less than or equal to that of SiO₂), such that the warping deformation of the wafer is addressed.

The semiconductor structures according to some embodiments of the present disclosure is applied in the field of semiconductor device preparation, and optionally, applied in the field of chip preparation.

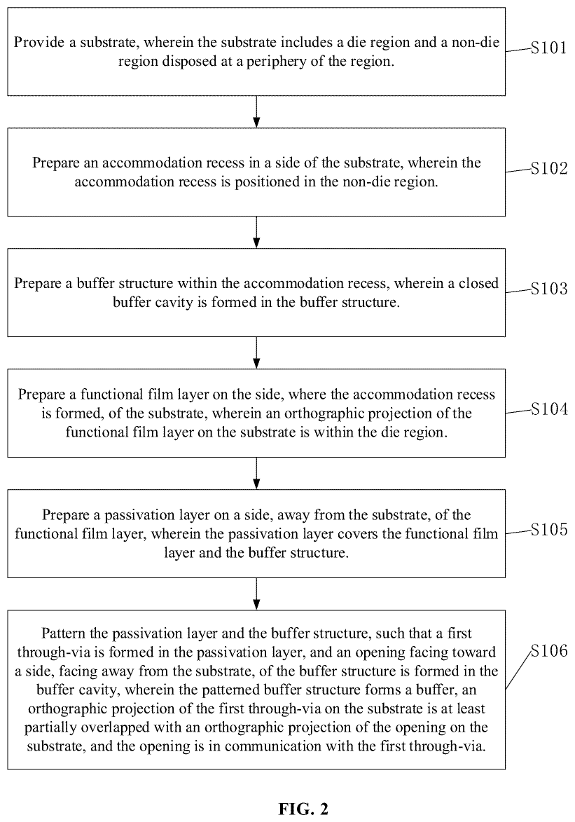

Based on the same inventive concept, some embodiments of the present disclosure provide a method for preparing a semiconductor structure. A flowchart of the method is shown in FIG. 2, and the method includes the following steps.

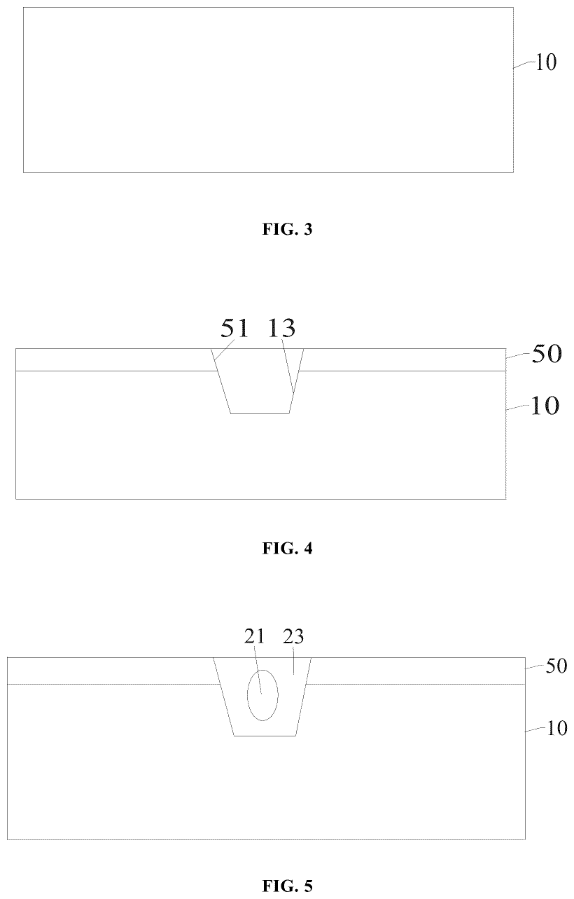

In S101, a substrate 10 is provided. The substrate 10 includes a die region 11 and a non-die region disposed at a periphery of the die region 11, as shown in FIG. 1 and FIG. 3.

In S102, an accommodation recess 13 is prepared in a side of the substrate 10. The accommodation recess 13 is disposed in the non-die region.

In S103, a buffer structure 23 is prepared within the accommodation recess 13. The buffer structure 23 has a closed buffer cavity 21 therein, as shown in FIG. 5.

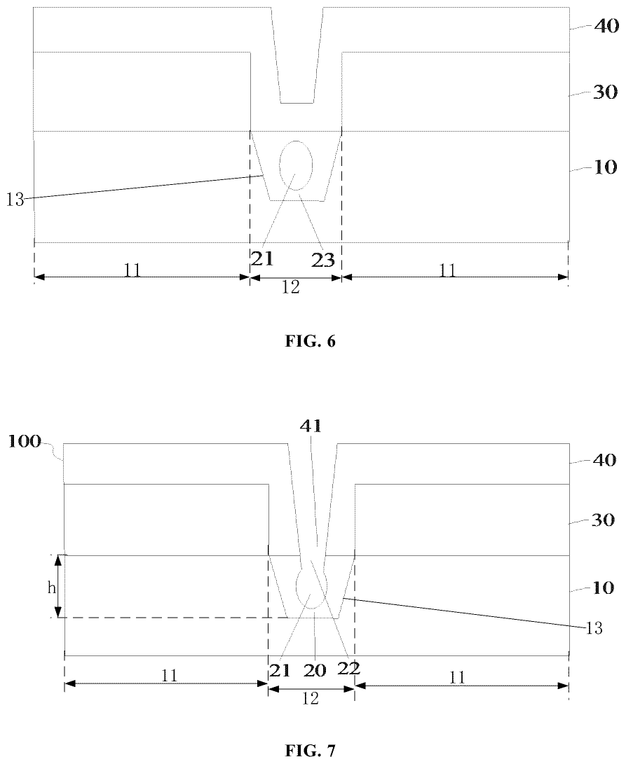

In S104, a functional film layer 30 is prepared on the side, where the accommodation recess 13 is formed, of the substrate 10. An orthographic projection of the functional film layer 30 on the substrate 10 is within the die region 11, as shown in FIG. 6 (the protection layer 50 is not shown in FIG. 6).

In S105, a passivation layer 40 is prepared on a side, away from the substrate 10, of the functional film layer 30. The passivation layer 40 covers the functional film layer 30 and the buffer structure 23, as shown in FIG. 6.

In S106, the passivation layer 40 and the buffer structure 23 are patterned, such that a first through-via 41 is formed in the passivation layer 40, and an opening 22 facing away from the substrate 10 is formed in the buffer cavity 21, wherein the patterned buffer structure 23 forms a buffer 20, an orthographic projection of the first through-via 41 on the substrate 10 is at least partially overlapped with an orthographic projection of the opening 22 on the substrate 10, and the opening 22 is in communication with the first through-via 41 as shown in FIG. 7 (the protection layer 50 is not shown in FIG. 7).

In some embodiments of the present disclosure, the method for preparing the semiconductor structure is employed to prepare the semiconductor structure according to any of the embodiments of the present disclosure.

In some embodiments of the present disclosure, the substrate 10 is configured to support the buffer 20, the functional film layer 30, and the passivation layer 40. The functional film layer 30 is disposed in the die region 11 of the substrate 10. The accommodation recess 13 is disposed in the non-die region of the substrate 10, and the accommodation recess 13 is configured to accommodate the buffer 20. The buffer 20 is disposed in the non-die region, and the buffer 20 has the buffer cavity 21 with the opening 22 facing toward the side, away from the accommodation recess 13, of the buffer 20. In this way, in the process of producing the semiconductor structure 100, in a case where the thermal stress is transferred to the buffer 20, due to the compressibility of the air, the buffer cavity 21 buffers the thermal stress and releases the thermal stress, such that the warping deformation of the wafer is alleviated or avoided, and thus the warping deformation of the wafer in the production process is addressed. Therefore, the impact of the thermal stress on the semiconductor structure 100 is reduced, and thus the production yield rate is improved, and the performance of the semiconductor structure is ensured.

In some embodiments of the present disclosure, the passivation layer 40 covers the functional film layer 30 and the substrate 10, the first through-via 41 is formed in the passivation layer 40, and the first through-via 41 is in communication with the opening 22, such that the buffer cavity 21 of the buffer 20 is in communication with the outside through the opening 22 and the first through-via 41 in sequence. In this way, the buffer cavity 21 buffers the thermal stress, such that the thermal stress is released timely and effectively, which helps to further enhance the improvement effect on the warping deformation of the wafer.

In some embodiments of the present disclosure, as shown in FIG. 4, prior to preparing the accommodation recess 13 in the side of the substrate 10, the method for preparing the semiconductor structure further includes: preparing a protection layer 50 on a side of the substrate 10. In some embodiments, the protection layer 50 is prepared by deposition, and the protection layer 50 protects the substrate 10, such that the functions of oxidation resistance and prevention of moisture invasion are achieved, and the etching solution is prevented from affecting regions of the substrate 10 other than the region where the accommodation recess 13 needs to be formed, especially the die region during the process of forming the accommodation recess 13.

In some embodiments of the present disclosure, as shown in FIG. 4, preparing the accommodation recess 13 in the side of the substrate 10 includes patterning the protection layer 50 and the substrate 10, such that a second through-via 51 is formed in the protection layer 50, and the accommodation recess 13 is formed in the substrate 10, wherein an orthographic projection of the second through-via 51 on the substrate 10 is at least partially overlapped with an orthographic projection of the accommodation recess 13 on the substrate 10.

Specifically, the second through-via 51 is etched in the protection layer 50 and the accommodation recess 13 is etched in the silicon substrate by processes such as photolithography, masking, and exposure, wherein the accommodation recess 13 is disposed in the scribe line region 12.

In some embodiments of the present disclosure, preparing the buffer structure 23 within the accommodation recess 13 includes: filling the accommodation recess 13 with a buffer material and forming the buffer structure 23 with the closed buffer cavity 21 by controlling a filling rate of the buffer material. A difference between a coefficient of thermal expansion of the buffer material and a coefficient of thermal expansion of the substrate 10 is within a first predetermined range, and the coefficient of thermal expansion of the buffer material is close to or less than the coefficient of thermal expansion of the substrate 10.

Specifically, the buffer structure 23 is formed by filling the accommodation recess 13 with a material with a low coefficient of thermal expansion (a material with a coefficient of thermal expansion less than or equal to that of SiO₂, such as SiO₂ or C), and the buffer structure 23 is made to have the buffer cavity 21 that is closed in a section perpendicular to the substrate 10. In some embodiments, the buffer structure 23 with the buffer cavity 21 is formed by controlling a rate at which the material of the buffer structure 23 is filled into the accommodation recess 13. In some embodiments, in a case where the filling rate is fast, it is easy to form the buffer structure 23 with the buffer cavity 21. In this case, the rate in which the material of the buffer structure 23 is filled into the accommodation recess 13 is appropriately increased to facilitate the formation of the buffer structure 23 having the buffer cavity 21. In some other embodiments of the present disclosure, according to the actual needs, other methods are employed to form the buffer structure 23 with the closed buffer cavity 21, such as adjusting the process parameters of the equipment for filling the buffer material.

In some embodiments of the present disclosure, as shown in FIG. 5, prior to preparing the functional film layer 30 on the side, where the accommodation recess 13 is formed, of the substrate 10, the method for preparing the semiconductor structure further includes: performing a planarization process on the protection layer 50 and the buffer structure 23, such that a surface of a side, away from the substrate 10, of the protection layer 50 is flush with a surface of a side, facing away from the substrate 10, of the buffer structure 23.

Specifically, in some embodiments of the present disclosure, the planarization process is performed on the surface of the side, away from the substrate 10, of the protection layer 50 and the buffer structure 23 by a chemical mechanical polishing (CMP) process to smooth the surface of the wafer.

It should be noted that in some embodiments of the present disclosure, the specific production processes and steps of the functional film layer 30 are similar to those in the related art (e.g., preparation processes of conventional chips, including photolithography, etching, and the like.), which are not repeated herein.

In some specific embodiments of the present disclosure, preparing the passivation layer 40 on the side, away from the substrate 10, of the functional film layer 30 includes: preparing the passivation layer 40 (on top of all metal layers) using a material with a low CTE (a material with a coefficient of thermal expansion less than or equal to that of SiO₂ such as SiO₂ or C), and thereafter, forming the buffer 20 by employing a deep-etching process in a region corresponding to the accommodation recess 13 of the substrate 10 to etch from above of the region until the buffer structure 23 is opened. The buffer 20 has the buffer cavity 21 therein, wherein the opening 22 of the buffer cavity 21 faces toward a side, facing away from the accommodation recess 13, of the buffer 20, and the buffer 20 within the accommodation recess 13 is exposed by the buffer cavity 21.

The technical solutions of the present disclosure are applied to the field of semiconductor device (e.g., semiconductor chip) production and manufacturing, relating to a semiconductor structure and corresponding film layer growth, masking, and trench etching processes.

It should be noted that the “patterning process” described in some embodiments of the present disclosure includes depositing a film layer, coating a photoresist, exposing a mask, developing, etching, stripping the photoresist, and other treatments, which is a mature preparation process in the related art. The “photolithography process” described herein includes coating a film layer, mask exposure and development, which is a mature preparation process in the relevant art. The deposition may adopt known processes such as sputtering, vapor deposition, chemical vapor deposition, and the like, the coating may adopt known coating processes, and the etching may adopt known methods, which are not limited herein.

Based on the same inventive concept, some embodiments of the present disclosure provide a memory. The memory includes the semiconductor structure 100 according to any of the above embodiments.

It should be noted that because the memory according to some embodiments of the present disclosure includes the semiconductor structure according to some embodiments of the present disclosure, the memory also achieves the above-described beneficial effects of the semiconductor structure according to some embodiments of the present disclosure, which are not repeated herein.

In some embodiments of the present disclosure, the semiconductor structure further includes a trench structure. The trench structure and the functional film layer 30 form a memory unit.

In some embodiments of the present disclosure, the memory is a random access memory, specifically a static random memory, a dynamic random memory, or a flash memory.

Based on the same inventive concept, some embodiments of the present disclosure provide an electronic device. The electronic device includes the memory according to any of the above embodiments.

It should be noted that because the electronic device according to some embodiments of the present disclosure includes the memory according to some embodiments of the present disclosure, the electronic device according to some embodiments of the present disclosure also has the above-described beneficial effects of the memory according to some embodiments of the present disclosure, which are not repeated herein.

In some embodiments of the present disclosure, the electronic device includes a storage device, a smartphone, a computer, a tablet, an artificial intelligence device, a wearable device, or a mobile power source, wherein the storage device includes a memory in a computer, which is not limited herein.

At least the following beneficial effects are achieved by applying the embodiments of the present disclosure.

In some embodiments of the present disclosure, the substrate is configured to support the buffer, the functional film layer, and the passivation layer. The functional film layer is disposed in the die region of the substrate. The accommodation recess is positioned in the non-die region of the substrate, and the accommodation recess is configured to accommodate the buffer. The buffer is disposed in the non-die region, and the buffer has the buffer cavity with the opening facing toward the side, away from the accommodation recess, of the buffer. In this way, in the process of producing the semiconductor structure, in a case where the thermal stress is transferred to the buffer, due to the compressibility of the air, the buffer cavity buffers the thermal stress and releases the thermal stress, such that the warping deformation of the wafer is alleviated or avoided, and thus the warping deformation of the wafer in the production process is addressed. Therefore, the impact of the thermal stress on the semiconductor structure is reduced, and thus the production yield rate is improved, and the performance of the semiconductor structure is ensured.

In some embodiments of the present disclosure, the passivation layer covers the functional film layer and the substrate, the first through-via is formed in the passivation layer, and the first through-via is in communication with the opening, such that the buffer cavity of the buffer is in communication with the outside through the opening and the first through-via in sequence. In this way, the buffer cavity buffers the thermal stress, such that the thermal stress is released timely and effectively, which helps to further enhance the improvement effect on the warping deformation of the wafer.

It should be understood by those skilled in the art that steps, measures, and solutions in the various operations, methods, and processes already discussed in the present disclosure may be alternated, changed, combined, or deleted. Further, other steps, measures, and solutions having the various operations, methods, and processes already discussed in the present disclosure may also be alternated, altered, rearranged, disassembled, combined, or deleted. Further, steps, measures, and solutions in the related art having the various operations, methods, and processes disclosed in the present disclosure may also be alternated, altered, rearranged, disassembled, combined, or deleted.

In the description of the present disclosure, the orientations or positional relationships indicated by the terms “center,” “up,” “down,” “front,” “back,” “left,” “right,” “vertical,” “horizontal,” “top,” “bottom,” “inside,” “outside,” and the like are exemplary orientations or positional relationships based on the accompanying drawings, are intended to facilitate the description of the embodiments of the present disclosure, or to simplify the description of the embodiments of the present disclosure, and are not intended to indicate or imply that the referred device or component must have a particular orientation, or be constructed and operated in a particular orientation, and therefore cannot be construed as a limitation to the present disclosure.

In the present disclosure, the terms “first” and “second” are only used for descriptive purposes, and cannot be understood as indicating or implying relative importance. As a result, features defined by the terms “first” or “second” may expressly or implicitly include one or more such features. The term “a plurality of” refers to two or more, unless expressly defined otherwise.

In the description of the present disclosure, it should be noted that unless expressly defined and defined otherwise, the terms “mounted,” “connected,” and “communicated” are understood in a broad sense, such as fixed connected, removable connected, or integrally connected; or directly connected, indirectly connected through an intermediate medium, or communicated within the two elements. The specific meaning of the above terms in this disclosure may be understood by those skilled in the art according to specific cases.

In the description of this specification, specific features, structures, materials, or characteristics may be combined in any one or more embodiments or examples properly.

It should be understood that although the individual steps in the flowchart of the accompanying drawings are shown sequentially as indicated by the arrows, the order in which these steps are implemented is not limited to the order indicated by the arrows. Unless expressly defined herein, in some implementation scenarios of the embodiments of the present disclosure, the steps in the respective processes may be performed in other orders as desired. Moreover, some or all of the steps in the respective flowcharts may include multiple sub-steps or multiple stages based on actual implementation scenarios. Some or all of these sub-steps or stages may be executed at the same moment or may be executed in different scenarios at different moments. The execution order of these sub-steps or stages may be flexibly configured according to the demand, which is not limited herein.

Described above are merely some exemplary embodiments of the present disclosure. It should be noted that, for those skilled in the art, without departing from the conception of the technical solutions of the present disclosure, other similar implementations based on the technical conception of the present disclosure are also within the scope of protection of the embodiments of the present disclosure.

1. A semiconductor structure, comprising:
a substrate comprising a die region and a non-die region disposed on a periphery of the die region, wherein an accommodation recess is formed in a side of the substrate, the accommodation recess being positioned in the non-die region;
a buffer disposed in the accommodation recess, wherein a buffer cavity with an opening facing toward a side, facing away from the substrate, of the buffer is formed in the buffer;
a functional film layer disposed on the side, where the accommodation recess is formed, of the substrate, wherein an orthographic projection of the functional film layer on the substrate is within the die region; and
a passivation layer covering the functional film layer and the substrate, wherein a first through-via is formed in the passivation layer, an orthographic projection of the first through-via on the substrate being at least partially overlapped with an orthographic projection of the opening on the substrate, and the opening being in communication with the first through-via.

2. The semiconductor structure according to claim 1, wherein along a direction perpendicular to the substrate, a depth of the accommodation recess is greater than or equal to 3 μm.

3. The semiconductor structure according to claim 1, wherein at least one of:
a difference between a coefficient of thermal expansion of the buffer and a coefficient of thermal expansion of the substrate is within a first predetermined range, and the coefficient of thermal expansion of the buffer is close to or less than the coefficient of thermal expansion of the substrate; or
a difference between a coefficient of thermal expansion of the passivation layer and a coefficient of thermal expansion of the substrate is within a second predetermined range, and the coefficient of thermal expansion of the passivation layer is close to or less than the coefficient of thermal expansion of the substrate.

4. The semiconductor structure according to claim 3, wherein:
the substrate is a silicon substrate;
the coefficient of thermal expansion of the buffer is greater than or equal to 0 and less than or equal to a coefficient of thermal expansion of silicon dioxide; and
the coefficient of thermal expansion of the passivation layer is greater than or equal to 0 and less than or equal to the coefficient of thermal expansion of silicon dioxide.

5. The semiconductor structure according to claim 4, wherein at least one of:
a material of the buffer comprises silicon dioxide or carbon; or
a material of the passivation layer comprises silicon dioxide or carbon.

6. The semiconductor structure according to claim 1, wherein at least one of:
in a section parallel to the substrate, a section of the accommodation groove is in a linear shape, the linear shape comprising at least one of a straight line shape, a folded line shape, or an arc shape; or
in a section perpendicular to the substrate, the accommodation recess is in a shape with a wide upper part and a narrow lower part, a shape with a narrow upper part and a wide lower part, a rectangular shape, a circular shape, or an elliptical shape.

7. The semiconductor structure according to claim 1, wherein a plurality of the accommodation recesses are formed in the side of the substrate, the plurality of the accommodation recesses being successively spaced apart along a predetermined direction or spaced apart in an array.

8. The semiconductor structure according to claim 1, further comprising: a protection layer, wherein the protection layer is formed on a side, facing toward the functional film layer, of the substrate, and a second through-via is formed in the protection layer, an orthographic projection of the second through-via on the substrate being at least partially overlapped with the orthographic projection of the opening on the substrate.

9. The semiconductor structure according to claim 8, wherein the buffer is filled into the accommodation recess and the second through-via, and wherein at least one of:
within a section perpendicular to the substrate, the buffer cavity is at least partially overlapped with the accommodation recess; or
within a section perpendicular to the substrate, the buffer cavity is at least partially overlapped with the second through-via.

10. A memory, comprising:
a semiconductor structure, wherein the semiconductor structure comprises:
a substrate comprising a die region and a non-die region disposed on a periphery of the die region, wherein an accommodation recess is formed in a side of the substrate, the accommodation recess being positioned in the non-die region;
a buffer disposed in the accommodation recess, wherein a buffer cavity with an opening facing toward a side, facing away from the substrate, of the buffer is formed in the buffer;
a functional film layer disposed on the side, where the accommodation recess is formed, of the substrate, wherein an orthographic projection of the functional film layer on the substrate is within the die region; and
a passivation layer covering the functional film layer and the substrate, wherein a first through-via is formed in the passivation layer, an orthographic projection of the first through-via on the substrate being at least partially overlapped with an orthographic projection of the opening on the substrate, and the opening being in communication with the first through-via.

11. (canceled)

12. A method for preparing a semiconductor structure, comprising:
providing a substrate, wherein the substrate comprises a die region and a non-die region disposed on a periphery of the die region;
preparing an accommodation recess in a side of the substrate, wherein the accommodation recess is positioned in the non-die region;
preparing a buffer structure within the accommodation recess, wherein a closed buffer cavity is formed in the buffer structure;
preparing a functional film layer on the side, where the accommodation recess is formed, of the substrate, wherein an orthographic projection of the functional film layer on the substrate is within the die region;
preparing a passivation layer on a side, away from the substrate, of the functional film layer, wherein the passivation layer covers the functional film layer and the buffer structure; and
patterning the passivation layer and the buffer structure, such that a first through-via is formed in the passivation layer, and an opening facing toward a side, facing away from the substrate, of the buffer structure is formed in the buffer cavity, wherein the patterned buffer structure forms a buffer, an orthographic projection of the first through-via on the substrate is at least partially overlapped with an orthographic projection of the opening on the substrate, and the opening is in communication with the first through-via.

13. The method according to claim 12, wherein prior to preparing the accommodation recess in the side of the substrate, the method further comprises:
preparing a protection layer on a side of the substrate, and
wherein preparing the accommodation recess in the side of the substrate comprises:
patterning the protection layer and the substrate, such that a second through-via is formed in the protection layer, and the accommodation recess is formed in the substrate, wherein an orthographic projection of the second through-via on the substrate is at least partially overlapped with an orthographic projection of the accommodation recess on the substrate.

14. The method according to claim 13, wherein preparing the buffer structure within the accommodation recess comprises:
filling the accommodation recess with a buffer material and forming the buffer structure with the closed buffer cavity by controlling a filling rate of the buffer material,
wherein a difference between a coefficient of thermal expansion of the buffer material and a coefficient of thermal expansion of the substrate is within a first predetermined range, and the coefficient of thermal expansion of the buffer material is close to or less than the coefficient of thermal expansion of the substrate.

15. The method according to claim 14, wherein prior to preparing the functional film layer on the side, where the accommodation recess is formed, of the substrate, the method further comprises:
performing a planarization process on the protection layer and the buffer structure, such that a surface of a side, away from the substrate, of the protection layer is flush with a surface of a side, facing away from the substrate, of the buffer structure.

16. The memory according to claim 10, wherein along a direction perpendicular to the substrate, a depth of the accommodation recess is greater than or equal to 3 μm.

17. The memory according to claim 10, wherein at least one of:
a difference between a coefficient of thermal expansion of the buffer and a coefficient of thermal expansion of the substrate is within a first predetermined range, and the coefficient of thermal expansion of the buffer is close to or less than the coefficient of thermal expansion of the substrate; or
a difference between a coefficient of thermal expansion of the passivation layer and a coefficient of thermal expansion of the substrate is within a second predetermined range, and the coefficient of thermal expansion of the passivation layer is close to or less than the coefficient of thermal expansion of the substrate.

18. The memory according to claim 17, wherein:
the substrate is a silicon substrate;
the coefficient of thermal expansion of the buffer is greater than or equal to 0 and less than or equal to a coefficient of thermal expansion of silicon dioxide; and
the coefficient of thermal expansion of the passivation layer is greater than or equal to 0 and less than or equal to the coefficient of thermal expansion of silicon dioxide.

19. The memory according to claim 18, wherein at least one of:
a material of the buffer comprises silicon dioxide or carbon; or
a material of the passivation layer comprises silicon dioxide or carbon.

20. The memory according to claim 10, wherein at least one of:
in a section parallel to the substrate, a section of the accommodation groove is in a linear shape, the linear shape comprising at least one of a straight line shape, a folded line shape, or an arc shape; or
in a section perpendicular to the substrate, the accommodation recess is in a shape with a wide upper part and a narrow lower part, a shape with a narrow upper part and a wide lower part, a rectangular shape, a circular shape, or an elliptical shape.

21. The memory according to claim 10, wherein a plurality of the accommodation recesses are formed in the side of the substrate, wherein the plurality of the accommodation recesses are successively spaced apart along a predetermined direction or spaced apart in an array.
